(19) United States
(12) Patent Application Publication
(10) Pub. No.: US 2022/0189769 A1
(43) Pub. Date: Jun. 16, 2022

(54) CRYSTAL FILM, SEMICONDUCTOR DEVICE INCLUDING CRYSTAL FILM, AND METHOD OF PRODUCING CRYSTAL FILM

(71) Applicants: FLOSFIA INC., Kyoto (JP); NATIONAL INSTITUTE FOR MATERIALS SCIENCE, Ibaraki (JP)

(72) Inventors: Katsuaki KAWARA, Kyoto (JP); Yuichi OSHIMA, Ibaraki (JP); Mitsuru OKIGAWA, Kyoto (JP)

(21) Appl. No.: 17/684,792

(22) Filed: Mar. 2, 2022

Related U.S. Application Data
(63) Continuation-in-part of application No. PCT/JP2020/031254, filed on Aug. 19, 2020.

(30) Foreign Application Priority Data
Sep. 3, 2019 (JP) 2019-160769
Sep. 3, 2019 (JP) 2019-160770

(51) Int. Cl. H01L 21/02; H01L 29/04

(52) U.S. Cl. CPC H01L 21/02433; H01L 21/0242; H01L 21/02483; H01L 29/045; H01L 21/02609; H01L 21/0262; H01L 21/02565

(57) ABSTRACT

There is provided a crystalline film including, a crystalline metal oxide as a major component; a corundum structure; a dislocation density of 1×10⁷ cm⁻² or less; and a surface area of 10 mm² or more. There is provided a method of producing a crystalline film comprising, forming a first lateral crystal growth layer on a substrate by first lateral crystal growth; placing a mask on the first lateral crystal growth layer; and forming a second lateral crystal growth layer by second lateral crystal growth.

### CROSS REFERENCE TO RELATED APPLICATION

This application is a continuation-in-part application of International Patent Application No. PCT/JP2020/031254 (Filed on Aug. 19, 2020), which claims the benefit of priority from Japanese Patent Application Nos. 2019-160769 (filed on Sep. 3, 2019) and 2019-160770 (filed on Sep. 3, 2019).

The entire contents of the above applications, which the present application is based on, are incorporated herein by reference.

### FIELD OF THE INVENTION

The present disclosure relates to a crystalline film that is useful for a semiconductor device. Moreover, the present disclosure relates to a semiconductor device. Furthermore, the present disclosure relates to a method of producing a crystalline film that is useful for a semiconductor device.

### DESCRIPTION OF THE RELATED ART

A semiconductor device using gallium oxide (Ga₂O₃) with a wide band gap receives attention as a next-generation switching element that can achieve high withstand voltage, low loss, and high heat resistance, and is expected to be applied to power semiconductor devices such as an inverter. Moreover, it is also expected that this semiconductor device finds wide application as light-receiving or emitting devices such as an LED and a sensor due to a wide band gap thereof. Among gallium oxide, α-Ga₂O₃ having a corundum structure and so forth, in particular, make band gap control possible by mixing thereinto indium or aluminum or a combination of indium and aluminum and form a very attractive family of material as InAlGaO-based semiconductors. Here, InAlGaO-based semiconductors indicate In_{X}Al_{Y}Ga_{Z}O₃ (0≤X≤2, 0≤Y≤2, 0≤Z≤2, X+Y+Z=1.5 to 2.5) and may be regarded as a family of materials including gallium oxide.

However, since the most stable phase of gallium oxide is a β gallia structure, it is difficult to form a crystalline film having a corundum structure which is a metastable phase unless a special film formation method is used. Moreover, α-Ga₂O₃ having a corundum structure is a metastable phase, which makes it impossible to use a bulk substrate obtained by melt growth. For these reasons, sapphire having the same crystal structure as α-Ga₂O₃ is used as a substrate at present. However, since the degree of lattice mismatch between α-Ga₂O₃ and sapphire is high, the dislocation density of an α-Ga₂O₃ crystalline film heteroepitaxially grown on a sapphire substrate tends to be high. Furthermore, there are still many problems not only in a crystalline film having a corundum structure, but also in, for example, improvements in film formation rate and crystal quality, prevention of cracks and abnormal growth, twin prevention, and a fracture in a substrate due to warpage. Under these circumstances, several studies of film formation of a crystalline semiconductor having a corundum structure are being conducted.

### SUMMARY OF THE INVENTION

According to an example of the present disclosure, there is provided a crystalline film including, a crystalline metal oxide as a major component; a corundum structure; a dislocation density of 1×10⁷ cm⁻² or less; and a surface area of 10 mm² or more.

According to an example of the present disclosure, there is provided a method of producing a crystalline film comprising, forming a first lateral crystal growth layer on a substrate by first lateral crystal growth; placing a mask on the first lateral crystal growth layer; and forming a second lateral crystal growth layer by second lateral crystal growth.

Thus, a crystalline film in an embodiment of the present disclosure is a large-area and high-quality crystalline film and useful for semiconductor devices and so forth. Moreover, a method of producing a crystalline film in an embodiment of the present disclosure makes it possible to produce, in an industrially advantageous manner, a large-area and high-quality crystalline film that is useful for semiconductor devices and so forth.

### BRIEF DESCRIPTION OF THE DRAWINGS

FIG. 1 is a diagram explaining a halide vapor phase epitaxy (HVPE) system that is suitably used in an embodiment of the present disclosure;

FIG. 2 is a schematic diagram showing one form of an uneven portion formed on a front surface of a substrate that is suitably used in an embodiment of the present disclosure;

FIG. 3 is a diagram schematically showing a front surface of the uneven portion formed on the front surface of the substrate that is suitably used in the embodiment of the present disclosure;

FIG. 4 is a schematic diagram showing one form of an uneven portion formed on a front surface of a substrate that is suitably used in an embodiment of the present disclosure;

FIG. 5 is a diagram schematically showing a front surface of the uneven portion formed on the front surface of the substrate that is suitably used in the embodiment of the present disclosure;

FIG. 6 is a schematic diagram showing one form of an uneven portion formed on a front surface of a substrate that is suitably used in an embodiment of the present disclosure; (a) being a schematic perspective view of the uneven portion and (b) being a schematic surface view of the uneven portion;

FIG. 7 is a schematic diagram showing one form of an uneven portion formed on a front surface of a substrate that is suitably used in an embodiment of the present disclosure; (a) being a schematic perspective view of the uneven portion and (b) being a schematic surface view of the uneven portion;

FIG. 8 is a diagram explaining mist CVD equipment used in an embodiment;

FIG. 9 is a diagram schematically showing the relationship between a mask and a first lateral crystal growth layer that were used in a first embodiment;

FIG. 10 is a diagram showing a planar TEM image in the first embodiment;

FIG. 11 is a diagram showing a selected area electron diffraction (SAED) pattern in the first embodiment;

FIG. 12 is a diagram showing a SEM image in the first embodiment;

FIG. 13 is a diagram showing an external view photograph of a film in the first embodiment; and

FIG. 14 shows a bird's-eye SEM image, a cross-sectional SEM image, and a cross-sectional SEM image (with inclination) obtained when a crystalline film was grown for varying lengths of growth time using a mask pattern of a second embodiment.

### DETAILED DESCRIPTION

Embodiments of the present disclosure will be described below with reference to the accompanying drawings. In the following description, the same parts and components are designated by the same reference numerals. The present embodiment includes, for example, the following disclosures.

### [Structure 1]

A crystalline film including, a crystalline metal oxide as a major component; a corundum structure; a dislocation density of 1×10⁷ cm⁻² or less; and a surface area of 10 mm² or more.

### [Structure 2]

The crystalline film according to [Structure 1], wherein the crystalline metal oxide contains at least gallium.

### [Structure 3]

The crystalline film according to [Structure 1] or [Structure 2], further including, two or more lateral crystal growth layers.

### [Structure 4]

A crystalline film including, a crystalline metal oxide as a major component; a corundum structure; at least one or more lateral crystal growth layers; and a surface area of 10 mm² or more.

### [Structure 5]

The crystalline film according to any one of [Structure 1] to [Structure 4], further including, dopant.

### [Structure 6]

A semiconductor device including, a crystalline film, wherein the crystalline film is the crystalline film according to any one of [Structure 1] to [Structure 5].

### [Structure 7]

The semiconductor device according to claim [Structure 6], wherein the semiconductor device is a power device.

### [Structure 8]

A method of producing a crystalline film including, forming a first lateral crystal growth layer on a substrate by first lateral crystal growth; placing a mask on the first lateral crystal growth layer; and forming a second lateral crystal growth layer by second lateral crystal growth.

### [Structure 9]

The production method according to [Structure 8], wherein the first lateral crystal growth is performed by HVPE or mist CVD.

### [Structure 10]

The production method according to [Structure 8] or [Structure 9], wherein the second lateral crystal growth is performed by HVPE or mist CVD.

### [Structure 11]

The production method according to any one of [Structure 8] to [Structure 10], wherein the mask is placed in a dot pattern on the first lateral crystal growth layer.

### [Structure 12]

The production method according to any one of claims [Structure 8] to [Structure 10], wherein the mask has openings having a dot pattern and is placed on the first lateral crystal growth layer.

### [Structure 13]

The production method according to any one of [Structure 8] to [Structure 10], wherein the mask has a line shape.

### [Structure 14]

The production method according to any one of [Structure 8] to [Structure 13], wherein the first lateral crystal growth layer has a corundum structure.

### [Structure 15]

The production method according to any one of [Structure 8] to [Structure 14], wherein the first lateral crystal growth layer contains gallium.

### [Structure 16]

The production method according to any one of [Structure 8] to [Structure 15], wherein the second lateral crystal growth layer has a corundum structure.

### [Structure 17]

The production method according to any one of [Structure 8] to [Structure 16], wherein the second lateral crystal growth layer contains gallium.

### [Structure 18]

The production method according to any one of [Structure 8] to [Structure 17], wherein the first lateral crystal growth layer includes two or more lateral crystal portions, and wherein the mask is placed on each of the two or more lateral crystal portions.

### [Structure 19]

The production method according to any one of [Structure 8] to [Structure 18], wherein the mask and/or openings are patterned at regular intervals in a regular manner.

### [Structure 20]

The production method according to any one of [Structure 8] to [Structure 19], wherein a mask is placed on a substrate and the first lateral crystal growth layer is formed by first lateral crystal growth.

### [Structure 21]

The production method according to [Structure 20], wherein the mask and/or openings on the substrate are patterned at regular intervals in a regular manner, and wherein a spacing of the mask and/or openings on the substrate is larger than a spacing of a mask on the first lateral crystal growth layer.

### [Structure 22]

The production method according to [Structure 21], wherein the spacing of the mask and/or openings on the substrate is 10 to 100 μm, and wherein the spacing of the mask and/or openings on the first lateral crystal growth layer is 1 to 50 μm.

As a first aspect of the present disclosure, a crystalline film including, a crystalline metal oxide as a major component; a corundum structure; a dislocation density of 1×10⁷ cm⁻² or less; and a surface area of 10 mm² or more. It is to be noted that a “dislocation density” refers to a dislocation density that is determined from the number of dislocations per unit area which are observed in a planar or cross-sectional TEM image. In the present disclosure, a dislocation density is more preferably 8.1×10⁶ cm⁻² or less and further preferably 5.5×10⁶ cm⁻² or less. The crystalline metal oxide is not limited to a particular crystalline metal oxide and suitable examples thereof include a metal oxide containing one or two or more types of metal selected from aluminum, gallium, indium, iron, chromium, vanadium, titanium, rhodium, nickel, cobalt, iridium and so forth. The crystal structure of the crystalline metal oxide is also not limited to a particular crystal structure; in the present disclosure, the crystal structure of the crystalline metal oxide is preferably a corundum structure or a β gallia structure and more preferably a corundum structure. In the present disclosure, the metal oxide preferably contains one or two or more types of elements selected from indium, aluminum, and gallium, more preferably contains at least indium or/and gallium, and most preferably contains at least gallium. A “major component” means that the crystalline metal oxide constitutes preferably 50% or more, more preferably 70% or more, and further preferably 90% or more of all the components of the crystalline film in terms of atom ratio and means that the crystalline metal oxide may constitute 100% of all the components of the crystalline film in terms of atom ratio. The crystalline film may be a conductive film or an insulating film; in the present disclosure, the crystalline film may contain dopant or the like and is preferably a semiconductor film. Moreover, it is preferable that the crystalline film includes two or more lateral crystal growth layers.

The crystalline film can be easily obtained by, for example, forming a first lateral crystal growth layer on a substrate by first lateral crystal growth, placing a mask on the first lateral crystal growth layer, and forming a second lateral crystal growth layer by second lateral crystal growth. As a second aspect of the present disclosure, a method of producing a crystalline film includes: forming a first lateral crystal growth layer on a substrate by first lateral crystal growth; placing a mask on the first lateral crystal growth layer; and forming a second lateral crystal growth layer by second lateral crystal growth. A “lateral crystal growth layer” generally refers to a crystal layer obtained by crystal growth performed on a crystal growth substrate in a direction that is not a direction (that is, a crystal growth direction) which is a crystal growth axis of a crystal growth surface; in the present disclosure, a “lateral crystal growth layer” is preferably a crystal layer obtained by crystal growth performed in a direction which forms an angle of less than 0.1 to 90° with the crystal growth direction, more preferably a crystal layer obtained by crystal growth performed in a direction which forms an angle of 1 to 88° with the crystal growth direction, and most preferably a crystal layer obtained by crystal growth performed in a direction which forms an angle of 5 to 85° with the crystal growth direction. It is preferable to apply HVPE or CVD such as mist CVD to each lateral crystal growth using a substrate with a front surface on which an uneven portion consisting of depressions or projections is formed. It is to be noted that, on the substrate, a groove may be provided or a mask from which at least a part of the front surface of the substrate is exposed may be placed and the first lateral crystal growth layer can be formed thereon. The above production method makes it possible to easily obtain, in particular, a crystalline film having a corundum structure, a dislocation density of 1×10⁷ cm⁻² or less, and a surface area of 10 mm² or more, the crystalline film including a crystalline metal oxide as a major component. It is to be noted that a “dislocation density” refers to a dislocation density that is determined from the number of dislocations per unit area which are observed in a planar or cross-sectional TEM image. In the present disclosure, a dislocation density is more preferably 8.1×10⁶ cm⁻² or less and further preferably 5.5×10⁶ cm⁻² or less. The crystalline metal oxide is not limited to a particular crystalline metal oxide and suitable examples thereof include a metal oxide containing one or two or more types of metal selected from aluminum, gallium, indium, iron, chromium, vanadium, titanium, rhodium, nickel, cobalt, iridium and so forth. The crystal structure of the crystalline metal oxide is also not limited to a particular crystal structure; in the present disclosure, the crystal structure of the crystalline metal oxide is preferably a corundum structure or a β gallia structure and more preferably a corundum structure. In the present disclosure, the metal oxide preferably contains one or two or more types of elements selected from indium, aluminum, and gallium, more preferably contains at least indium or/and gallium, and most preferably contains at least gallium. A “major component” means that the crystalline metal oxide constitutes preferably 50% or more, more preferably 70% or more, and further preferably 90% or more of all the components of the crystalline film in terms of atom ratio and means that the crystalline metal oxide may constitute 100% of all the components of the crystalline film in terms of atom ratio. The crystalline film may be a conductive film or an insulating film; in the present disclosure, the crystalline film may contain dopant or the like and is preferably a semiconductor film. Moreover, in the present disclosure, it is preferable that the first lateral crystal growth layer has a corundum structure and it is also preferable that the first lateral crystal growth layer contains gallium. Furthermore, in the present disclosure, it is preferable that the second lateral crystal growth layer has a corundum structure and it is also preferable that the second lateral crystal growth layer contains gallium. In the present disclosure, since a crystalline film that is useful for a semiconductor device can be obtained, the crystalline film is preferably a semiconductor film and more preferably a wide-band-gap semiconductor film.

Hereinafter, one example of a method of forming the first lateral crystal growth layer using HVPE mentioned above will be described.

One of embodiments of HVPE mentioned above is as follows: when film formation is performed by gasifying a metal source containing metal to obtain metal-containing source gas and supplying the metal-containing source gas and oxygen-containing source gas to the space above a substrate inside a reaction chamber, a substrate with a front surface on which an uneven portion consisting of depressions or projections is formed is used, reactive gas is supplied to the space above the substrate, and the film formation is performed with the reactive gas being circulated.

### (Metal Source)

The metal source is not limited to a particular metal source as long as the metal source contains metal and can be gasified, and the metal source may be elemental metal or a metal compound. Examples of the metal include one or two or more types of metal selected from gallium, aluminum, indium, iron, chromium, vanadium, titanium, rhodium, nickel, cobalt, iridium and so forth. In an embodiment of the present disclosure, the metal is preferably one or two or more types of metal selected from gallium, aluminum, and indium and more preferably gallium, and the metal source is most preferably elemental gallium. Moreover, the metal source may be gas, liquid, or solid; in an embodiment of the present disclosure, when gallium is used as the metal, for example, it is preferable that the metal source is liquid.

A method of the gasification is not limited to a particular method unless it interferes with the present disclosure, and may be a publicly known method. In an embodiment of the present disclosure, it is preferable that the method of the gasification is performed by halogenating the metal source. A halogenating agent that is used in the halogenation is not limited to a particular halogenating agent as long as the halogenating agent can halogenate the metal source, and may be a publicly known halogenating agent. Examples of the halogenating agent include halogens, hydrogen halides, or the like. Examples of the halogens include fluorine, chlorine, bromine, iodine, or the like. Moreover, examples of the hydrogen halides include hydrogen fluoride, hydrogen chloride, hydrogen bromide, and hydrogen iodide. In an embodiment of the present disclosure, a hydrogen halide is preferably used in the halogenation and hydrogen chloride is more preferably used in the halogenation. In an embodiment of the present disclosure, it is preferable that the gasification is performed by supplying a halogen or hydrogen halide to the metal source as a halogenating agent and making the metal source and the halogen or hydrogen halide react with each other at a temperature equal to or higher than a vaporization temperature of a metal halide to form a metal halide. The halogenation temperature is not limited to a particular temperature; in an embodiment of the present disclosure, when, for example, the metal source is gallium and the halogenating agent is HCl, the halogenation temperature is preferably 900° C. or lower, more preferably 700° C. or lower, and most preferably 400 to 700° C. The metal-containing source gas is not limited to particular metal-containing source gas as long as the metal-containing source gas is gas containing metal of the metal source. Examples of the metal-containing source gas include a halide (such as fluoride, chloride, bromide, or iodide) of the metal.

In an embodiment of the present disclosure, after a metal source containing metal is gasified to obtain metal-containing source gas, the metal-containing source gas and the oxygen-containing source gas are supplied to the space above a substrate inside the reaction chamber. Moreover, in an embodiment of the present disclosure, reactive gas is supplied to the space above the substrate. Examples of the oxygen-containing source gas include O₂ gas, CO₂ gas, NO gas, NO₂ gas, N₂O gas, H₂O gas, O₃ gas, or the like. In an embodiment of the present disclosure, the oxygen-containing source gas is preferably one or two or more types of gas selected from a group consisting of O₂, H₂O, and N₂O and more preferably contains O₂. It is to be noted that the oxygen-containing source gas may contain CO₂ as one of embodiments. The reactive gas is generally reactive gas that is different from metal-containing source gas and oxygen-containing source gas and inert gas is not included therein. The reactive gas is not limited to particular reactive gas and examples thereof include etching gas. The etching gas is not limited to particular etching gas unless it interferes with the present disclosure, and may be publicly known etching gas. In an embodiment of the present disclosure, the reactive gas is preferably halogen gas (for example, fluorine gas, chlorine gas, bromine gas, or iodine gas), hydrogen halide gas (for example, hydrofluoric acid gas, hydrochloric acid gas, hydrobromic gas, and hydrogen iodide gas), hydrogen gas, mixed gas of two or more of these gases, or the like, more preferably contains hydrogen halide gas, and most preferably contains hydrogen chloride. It is to be noted that the metal-containing source gas, the oxygen-containing source gas, and the reactive gas may contain carrier gas. Examples of the carrier gas include inert gas such as nitrogen and argon. Moreover, the partial pressure of the metal-containing source gas is not limited to a particular partial pressure; in an embodiment of the present disclosure, the partial pressure of the metal-containing source gas is preferably 0.5 Pa to 1 kPa and more preferably 5 Pa to 0.5 kPa. The partial pressure of the oxygen-containing source gas is not limited to a particular partial pressure; in an embodiment of the present disclosure, the partial pressure of the oxygen-containing source gas is preferably 0.5 to 100 times higher than the partial pressure of the metal-containing source gas and more preferably 1 to 20 times higher than the partial pressure of the metal-containing source gas. The partial pressure of the reactive gas is also not limited to a particular partial pressure; in an embodiment of the present disclosure, the partial pressure of the reactive gas is preferably 0.1 to 5 times higher than the partial pressure of the metal-containing source gas and more preferably 0.2 to 3 times higher than the partial pressure of the metal-containing source gas.

Furthermore, in an embodiment of the present disclosure, it is also preferable to supply dopant-containing source gas to the substrate. The dopant-containing source gas is not limited to particular dopant-containing source gas as long as the dopant-containing source gas contains dopant. The dopant is also not limited to particular dopant; in an embodiment of the present disclosure, the dopant preferably contains one or two or more types of elements selected from germanium, silicon, titanium, zirconium, vanadium, niobium, and tin, more preferably contains germanium, silicon, or tin, and most preferably contains germanium. By using the dopant-containing source gas as described above, it is possible to easily control the conductivity of a film to be obtained. The dopant-containing source gas preferably contains the dopant in the form of a compound (for example, a halide or oxide) and more preferably contains the dopant in the form of a halide. The partial pressure of the dopant-containing source gas is not limited to a particular partial pressure; in an embodiment of the present disclosure, the partial pressure of the dopant-containing source gas is preferably 1×10⁻⁷ to 0.1 times higher than the partial pressure of the metal-containing source gas and more preferably 2.5×10⁻⁶ to 7.5×10⁻² times higher than the partial pressure of the metal-containing source gas. It is to be noted that, in an embodiment of the present disclosure, it is preferable to supply the dopant-containing source gas to the space above the substrate along with the reactive gas.

### (Substrate)

The substrate is not limited to a particular substrate as long as the substrate has a plate-like shape, has a front surface on which an uneven portion consisting of depressions or projections is formed, and can support the crystalline film, and may be a publicly known substrate. The substrate may be an insulator substrate, a conductive substrate, or a semiconductor substrate. In an embodiment of the present disclosure, it is preferable that the substrate is a crystal substrate.

### (Crystal Substrate)

The crystal substrate is not limited to a particular crystal substrate as long as the crystal substrate is a substrate containing a crystal substance as a major component, and may be a publicly known substrate. The crystal substrate may be an insulator substrate, a conductive substrate, or a semiconductor substrate. The crystal substrate may be a monocrystalline substrate or a polycrystalline substrate. Examples of the crystal substrate include a substrate containing a crystal substance having a corundum structure as a major component, a substrate containing a crystal substance having a β-gallia structure as a major component, a substrate having a hexagonal structure, or the like. It is to be noted that the “major component” refers to the crystal substance constituting 50% or more, preferably 70% or more, and more preferably 90% or more of the substrate in terms of composition ratio.

Examples of the substrate containing a crystal substance having a corundum structure as a major component include a sapphire substrate and an α-type gallium oxide substrate. Examples of the substrate containing a crystal substance having a β-gallia structure as a major component include a β-Ga₂O₃ substrate, a mixed crystal substrate containing β-Ga₂O₃ and Al₂O₃, or the like. It is to be noted that suitable examples of the mixed crystal substrate containing β-Ga₂O₃ and Al₂O₃ include a mixed crystal substrate with an Al₂O₃ content of more than 0% and 60% or less in terms of atom ratio. Moreover, examples of the substrate having a hexagonal structure include a SiC substrate, a ZnO substrate, and a GaN substrate. Examples of other crystal substrates include a Si substrate.

In an embodiment of the present disclosure, it is preferable that the crystal substrate is a sapphire substrate. Examples of the sapphire substrate include a c-plane sapphire substrate, an m-plane sapphire substrate, and an a-plane sapphire substrate. Moreover, the sapphire substrate may have an off angle. The off angle is not limited to a particular angle and is preferably 0 to 15°. It is to be noted that the thickness of the crystal substrate is not limited to a particular thickness and is preferably 50 to 2000 μm and more preferably 200 to 800 μm.

Moreover, in one of embodiments of the present disclosure, since the substrate has a front surface on which an uneven portion consisting of depressions or projections is formed, it is possible to obtain the first lateral crystal growth layer of higher quality more efficiently. The uneven portion is not limited to a particular uneven portion as long as the uneven portion consists of projections or depressions; the uneven portion may be an uneven portion consisting of projections, an uneven portion consisting of depressions, or an uneven portion consisting of projections and depressions. Furthermore, the uneven portion may be formed of regular projections or depressions or formed of irregular projections or depressions. In an embodiment of the present disclosure, the uneven portion is preferably formed at regular intervals and more preferably patterned at regular intervals in a regular manner, and the uneven portion is most preferably a mask consisting of projections and patterned at regular intervals in a regular manner. The pattern of the uneven portion is not limited to a particular pattern and examples of the pattern include a striped pattern, a dot pattern, a meshed pattern, a random pattern, or the like; in an embodiment of the present disclosure, the pattern of the uneven portion is preferably a dot pattern or a striped pattern and more preferably a dot pattern. It is to be noted that the dot pattern or the striped pattern may be the shape of openings of the projections. Moreover, when the uneven portion is patterned at regular intervals in a regular manner, it is preferable that the pattern shape of the uneven portion is a polygonal shape such as a triangle, a quadrangle (for example, a square, a rectangle, or a trapezoid), a pentagon, or a hexagon or a shape such as a circle or an ellipse. It is to be noted that, when an uneven portion is formed in a dot pattern, a lattice shape such as a tetragonal lattice, an orthorhombic lattice, a triangular lattice, or a hexagonal lattice is preferably adopted as a dot lattice shape and the lattice shape of a triangular lattice is more preferably adopted as a dot lattice shape. The cross-sectional shape of the depressions or projections of the uneven portion is not limited to a particular cross-sectional shape, and examples of the cross-sectional shape of the depressions or projections of the uneven portion include the shape of a backward C, the shape of a U, the shape of an inverted U, a wave shape, a polygon such as a triangle, a quadrangle (for example, a square, a rectangle, or a trapezoid), a pentagon, or a hexagon, or the like.

A constituent material for the projections is not limited to a particular constituent material, and may be a publicly known mask material. The constituent material for the projections may be an insulator material, a conductor material, or a semiconductor material. Moreover, the constituent material may be amorphous, monocrystalline, or polycrystalline. Examples of the constituent material for the projections include oxides, nitrides, or carbides of Si, Ge, Ti, Zr, Hf, Ta, Sn, or the like, carbon, diamond, metal, and a mixture of these materials. More specifically, examples of the constituent material for the projections include a Si-containing compound containing SiO₂, SiN, or polycrystalline silicon as a major component and metal (for example, noble metal such as platinum, gold, silver, palladium, rhodium, iridium, and ruthenium) having a melting point higher than the crystal growth temperature of the crystalline oxide semiconductor. It is to be noted that the content of the constituent material in the projections is preferably 50% or more, more preferably 70% or more, and most preferably 90% or more in terms of composition ratio.

A method of forming the projections may be a publicly known method and examples thereof include a publicly known patterning method such as photolithography, electron-beam lithography, laser patterning, and etching (for example, dry etching or wet etching) that is performed afterward. In an embodiment of the present disclosure, the projections preferably have a striped pattern or a dot pattern and more preferably have a dot pattern. It is to be noted that the dot pattern or the striped pattern may be the shape of openings of the projections. Moreover, in an embodiment of the present disclosure, it is also preferable that the crystal substrate is a patterned sapphire substrate (PSS). The pattern shape of the PSS is not limited to a particular pattern shape and may be a publicly known pattern shape. Examples of the pattern shape include a conical shape, a bell shape, a dome shape, a hemisphere shape, and a square or triangular pyramid shape; in an embodiment of the present disclosure, it is preferable that the pattern shape is a conical shape. Furthermore, the pitch of the pattern shape is also not limited to a particular pitch; in an embodiment of the present disclosure, the pitch of the pattern shape is preferably 100 μm or less and more preferably 1 to 50 μm.

The depressions are not limited to particular depressions, and may be what is similar to the constituent material for the projections mentioned above or a substrate. In an embodiment of the present disclosure, it is preferable that the depressions are a gap layer provided on a front surface of a substrate. A method similar to the method of forming the projections can be used as a method of forming the depressions. The gap layer can be formed on a front surface of a substrate by providing a groove in the substrate by a publicly known groove formation method. The groove width, the groove depth, the terrace width and so forth of the gap layer are not limited to particular groove width, groove depth, terrace width and so forth unless they interfere with the present disclosure, and can be appropriately set. Moreover, the gap layer may contain air or may contain inert gas or the like.

Hereinafter, one example of an embodiment of a substrate that is suitably used in an embodiment of the present disclosure will be described using the drawings.

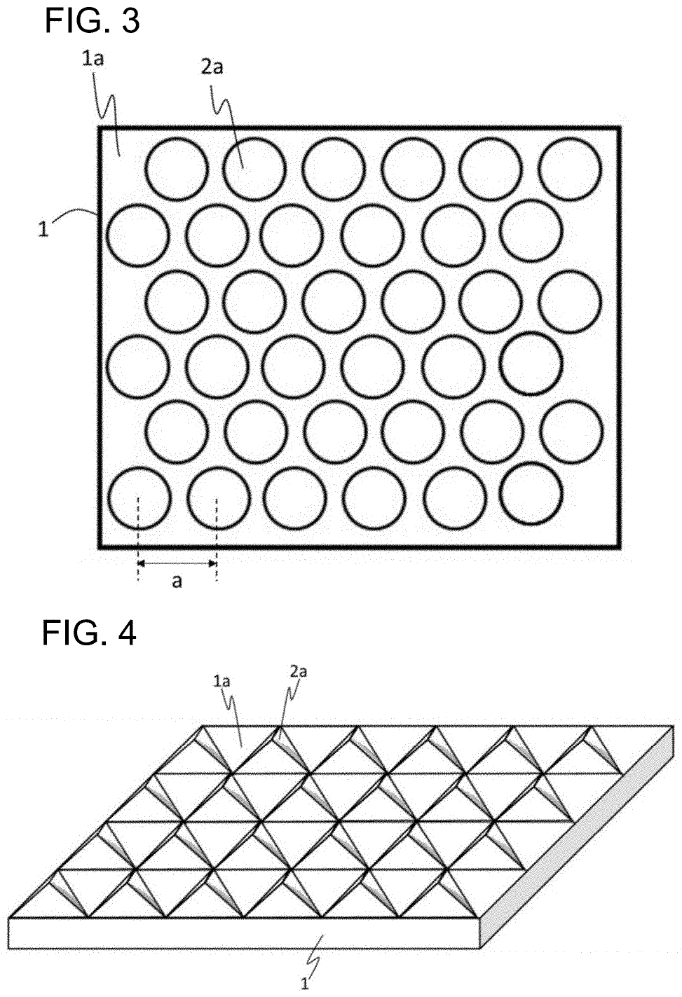

FIG. 2 shows one form of an uneven portion having a dot pattern and provided on a front surface of a substrate in an embodiment of the present disclosure. The uneven portion of FIG. 2 is configured with a substrate main body 1 and a plurality of projections 2a provided on a front surface 1a of a substrate. FIG. 3 shows a front surface of the uneven portion shown in FIG. 2 and viewed from a zenith direction. As is clear from FIGS. 2 and 3, the uneven portion has a configuration in which the conical projections 2a are formed on a triangular lattice on the front surface 1a of the substrate. The projections 2a can be formed by a publicly known processing method such as photolithography. It is to be noted that lattice points of the triangular lattice are provided at spacings of a fixed interval a. The interval a is not limited to a particular interval; in an embodiment of the present disclosure, the interval a is preferably 100 μm or less and more preferably 1 to 50 μm. The interval a here refers to the distance between the height peak positions (that is, lattice points) of adjacent projections 2a.

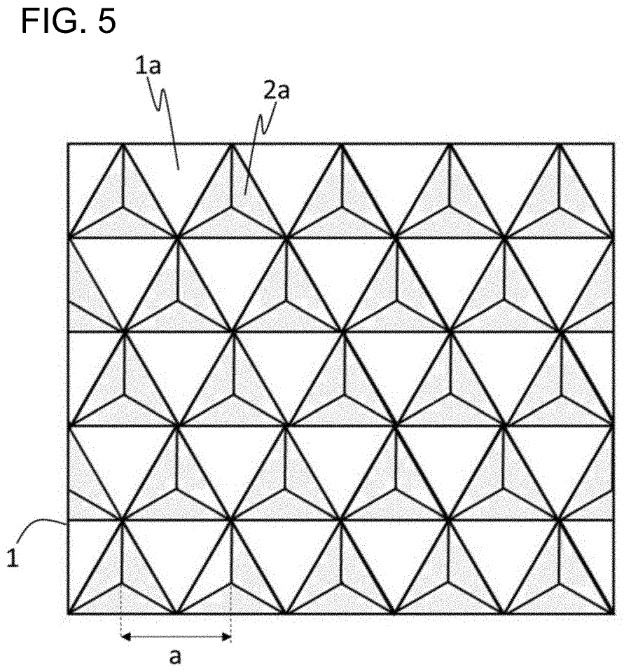

FIG. 4 shows one form of an uneven portion having a dot pattern and provided on a front surface of a substrate in an embodiment of the present disclosure and shows a form different from the form of FIG. 2. The uneven portion of FIG. 4 is configured with a substrate main body 1 and projections 2a provided on a front surface 1a of a substrate. FIG. 5 shows a front surface of the uneven portion shown in FIG. 4 and viewed from a zenith direction. As is clear from FIGS. 4 and 5, the uneven portion has a configuration in which the triangular pyramid projections 2a are formed on a triangular lattice on the front surface 1a of the substrate. The projections 2a can be formed by a publicly known processing method such as photolithography. It is to be noted that lattice points of the triangular lattice are provided at spacings of a fixed interval a. The interval a is not limited to a particular interval; in an embodiment of the present disclosure, the interval a is preferably 0.5 to 10 μm, more preferably 1 to 5 μm, and most preferably 1 to 3 μm.

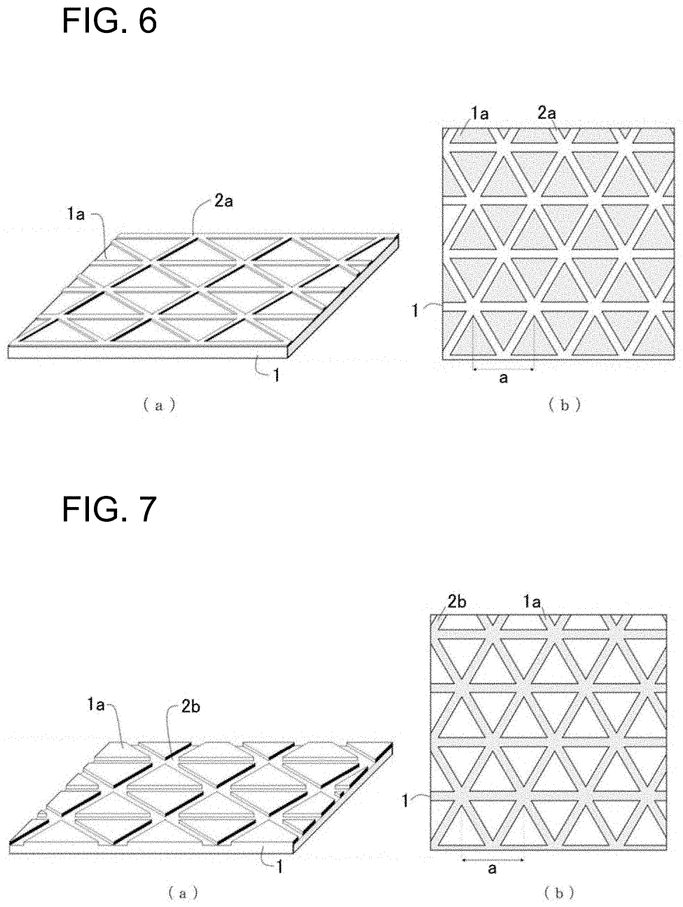

FIG. 6(a) shows one form of an uneven portion provided on a front surface of a substrate in an embodiment of the present disclosure and FIG. 6(b) schematically shows a front surface of the uneven portion shown in FIG. 6(a). The uneven portion of FIG. 6 is configured with a substrate main body 1 and projections 2a having a triangular pattern shape and provided on a front surface 1a of a substrate. It is to be noted that the projections 2a are formed of a material for the substrate or a silicon-containing compound such as SiO₂ and can be formed using a publicly known method such as photolithography. It is to be noted that an interval a between intersection points of the triangular pattern shape is not limited to a particular interval; in an embodiment of the present disclosure, the interval a is preferably 0.5 to 10 μm and more preferably 1 to 5 μm.

As in the case of FIG. 6(a), FIG. 7(a) shows one form of an uneven portion provided on a front surface of a substrate in an embodiment of the present disclosure, and FIG. 7(b) schematically shows a front surface of the uneven portion shown in FIG. 7(a). The uneven portion of FIG. 7(a) is configured with a substrate main body 1 and a gap layer having a triangular pattern shape. It is to be noted that depressions 2b can be formed by a publicly known groove formation method such as laser dicing. It is to be noted that an interval a between intersection points of the triangular pattern shape is not limited to a particular interval; in an embodiment of the present disclosure, the interval a is preferably 0.5 to 10 μm and more preferably 1 to 5 μm.

The width and height of projections of an uneven portion and the width and depth of depressions, the spacing between the depressions and so forth are not limited to particular width, height, depth, spacing and so forth; in an embodiment of the present disclosure, each of them falls within the range of about 10 nm to about 1 mm, for example; each of them is preferably about 10 nm to about 300 μm, more preferably about 10 nm to about 1 μm, and most preferably about 100 nm to about 1 μm. It is to be noted that the uneven portion may be formed directly on the substrate or provided with another layer placed between the uneven portion and the substrate.

In an embodiment of the present disclosure, a buffer layer including a stress relaxation layer and so forth may be provided on the substrate; when the buffer layer is provided, the uneven portion may also be formed on the buffer layer. Moreover, in an embodiment of the present disclosure, it is preferable that the substrate has the buffer layer in a part of a front surface or all over the front surface. A method of forming the buffer layer is not limited to a particular method and may be a publicly known method. Examples of the formation method include a spray method, mist CVD, HVPE, MBE, MOCVD, and a sputtering process. In an embodiment of the present disclosure, the buffer layer formed by mist CVD is preferable because this makes it possible to make the first lateral crystal growth layer that is formed on the buffer layer have higher crystallinity and to prevent a crystal defect such as tilt in particular. Hereinafter, a preferred embodiment in which the buffer layer is formed by mist CVD will be described in more detail.

The buffer layer can be suitably formed by, for example, atomizing a raw material solution (an atomization process), conveying the obtained atomized droplets (including mist) to the substrate by carrier gas (a conveying process), and then making the atomized droplets thermally react with each other in at least a part of a front surface of the substrate (a buffer layer formation process). It is to be noted that the buffer layer can also be formed by making the atomized droplets thermally react with each other all over the front surface of the substrate.

### (Atomization Process)

The atomization process atomizes the raw material solution and generates atomized droplets. A method of atomizing the raw material solution is not limited to a particular method as long as the method can atomize the raw material solution, and may be a publicly known method; in the embodiment of the present disclosure, an atomization method using ultrasonic waves is preferable. The atomized droplets obtained using ultrasonic waves are preferable because the initial velocity thereof is zero, which allows them to be suspended in the air, and are very suitable because they are atomized droplets that are suspended in the space and can be conveyed as gas, not being sprayed like a spray, for example, and therefore cause no damage by collision energy. The size of a droplet is not limited to a particular size and may be a droplet of about a few mm; the size of a droplet is preferably 50 μm or less and more preferably 0.1 to 10 μm.

### (Raw Material Solution)

The raw material solution is not limited to a particular raw material solution as long as the raw material solution is a solution that allows the buffer layer to be obtained by mist CVD. Examples of the raw material solution include an aqueous solution of an organometallic complex (for example, an acetylacetonato complex) or a halide (for example, fluoride, chloride, bromide, or iodide) of metal for atomization. The metal for atomization is not limited to particular metal, and examples of such metal for atomization include one or two or more types of metal selected from aluminum, gallium, indium, iron, chromium, vanadium, titanium, rhodium, nickel, cobalt, iridium and so forth. In an embodiment of the present disclosure, the metal for atomization preferably contains at least gallium, indium, or aluminum and more preferably contains at least gallium. The content of the metal for atomization in the raw material solution is not limited to a particular content unless it interferes with the present disclosure; the content of the metal for atomization in the raw material solution is preferably 0.001 to 50 mol % and more preferably 0.01 to 50 mol %.

Moreover, it is also preferable that the raw material solution contains dopant. By making the raw material solution contain dopant, it is possible to easily control the electrical conductivity of the buffer layer without a breakdown of a crystal structure without performing ion implantation or the like. In an embodiment of the present disclosure, the dopant is preferably tin, germanium, or silicon, more preferably tin or germanium, and most preferably tin. In general, the concentration of the dopant may be about 1×10¹⁶/cm³ to 1×10²²/cm³; the concentration of the dopant may be set at a low concentration of about 1×10¹⁷/cm³ or less or the raw material solution may be made to contain the dopant at a high concentration of about 1×10²⁰/cm³ or more. In an embodiment of the present disclosure, the concentration of the dopant is preferably 1×10²⁰/cm³ or less and more preferably 5×10¹⁹/cm³ or less.

A solvent of the raw material solution is not limited to a particular solvent and may be an inorganic solvent such as water, an organic solvent such as alcohol, or a mixed solvent of an inorganic solvent and an organic solvent. In an embodiment of the present disclosure, the solvent preferably contains water, is more preferably water or a mixed solvent of water and alcohol, and is most preferably water. More specifically, examples of the water include pure water, ultrapure water, tap water, well water, mineral water, mineralized water, hot spring water, spring water, fresh water, and seawater; in an embodiment of the present disclosure, ultrapure water is preferable.

### (Conveying Process)

In the conveying process, the mist or droplets are conveyed into a film formation chamber by carrier gas. The carrier gas is not limited to particular carrier gas unless it interferes with the present disclosure, and suitable examples of the carrier gas include oxygen, ozone, inert gas such as nitrogen and argon, reducing gas such as hydrogen gas and forming gas, or the like. Moreover, one type of carrier gas may be used; two or more types of carrier gas may be used and dilution gas (for example, 10-fold dilution gas) with a decreased flow rate, for example, may be additionally used as second carrier gas. Furthermore, instead of one carrier gas supply point, two or more carrier gas supply points may be provided. The flow rate of carrier gas is not limited to a particular flow rate and is preferably 0.01 to 20 L/min and more preferably 1 to 10 L/min. When dilution gas is used, the flow rate of the dilution gas is preferably 0.001 to 2 L/min and more preferably 0.1 to 1 L/min.

### (Buffer Layer Formation Process)

In the buffer layer formation process, the buffer layer is formed on a substrate by making the mist or droplets thermally react with each other inside the film formation chamber. A thermal reaction only has to make the mist or droplets react with each other by heat, and the reaction conditions and so forth are also not limited to particular reaction conditions and so forth unless they interfere with the present disclosure. In this process, the thermal reaction is generally carried out at a temperature equal to or higher than the evaporation temperature of a solvent; the temperature is preferably not too high temperatures (for example, 1000° C.) or lower, more preferably 650° C. or lower, and most preferably 400 to 650° C. Moreover, the thermal reaction may be carried out under any one of the following atmospheres: under vacuum, under a non-oxygen atmosphere, under a reducing gas atmosphere, and under an oxygen atmosphere and may be carried out under any one of the following conditions: under atmospheric pressure, under increased pressure, and under reduced pressure unless it interferes with the present disclosure; in an embodiment of the present disclosure, it is preferable that the thermal reaction is carried out under atmospheric pressure. It is to be noted that the thickness of the buffer layer can be set by adjusting the formation time.

After the buffer layer is formed in a part of a front surface or all over the front surface on the substrate in the above-mentioned manner, the first lateral crystal growth layer is formed on the buffer layer by a method of forming the first lateral crystal growth layer in the above-mentioned embodiment of the present disclosure, which makes it possible to further reduce the number of defects such as tilt in the first lateral crystal growth layer and thereby further improve film quality.

Moreover, the buffer layer is not limited to a particular buffer layer; in an embodiment of the present disclosure, it is preferable that the buffer layer contains a metal oxide as a major component. Examples of the metal oxide include a metal oxide containing one or two or more types of metal selected from aluminum, gallium, indium, iron, chromium, vanadium, titanium, rhodium, nickel, cobalt, iridium and so forth. In the disclosure, the metal oxide preferably contains one or two or more types of elements selected from indium, aluminum, and gallium, more preferably contains at least indium or/and gallium, and most preferably contains at least gallium. As one of embodiments of a film formation method of the present disclosure, the buffer layer may contain a metal oxide as a major component and the metal oxide contained in the buffer layer may contain gallium and have a lower content of aluminum than that of gallium. By using the buffer layer having a lower content of aluminum than that of gallium, it is possible not only to make crystal growth satisfactory, but also to achieve satisfactory high-temperature growth. Furthermore, as one of embodiments of the film formation method of the present disclosure, the buffer layer may contain a superlattice structure. Using the buffer layer containing a superlattice structure not only achieves satisfactory crystal growth, but also makes it easier to prevent warpage and the like at the time of crystal growth. It is to be noted that, in the present disclosure, a “major component” means that the metal oxide constitutes preferably 50% or more, more preferably 70% or more, and further preferably 90% or more of all the components of the buffer layer in terms of atom ratio and means that the metal oxide may constitute 100% of all the components of the buffer layer in terms of atom ratio. The crystal structure of the crystalline oxide semiconductor is not limited to a particular crystal structure; in an embodiment of the present disclosure, the crystal structure of the crystalline oxide semiconductor is preferably a corundum structure or a β gallia structure and more preferably a corundum structure. Moreover, a major component of the first lateral crystal growth layer and a major component of the buffer layer may be the same or different from each other unless it interferes with the present disclosure; in an embodiment of the present disclosure, it is preferable that a major component of the first lateral crystal growth layer and a major component of the buffer layer are the same.

In the embodiment of the present disclosure, metal-containing source gas, oxygen-containing source gas, reactive gas, and dopant-containing source gas if necessary are supplied to the space above the substrate on which the buffer layer may be provided, and film formation is performed with the reactive gas being circulated. In an embodiment of the present disclosure, it is preferable that the film formation is performed on the heated substrate. The film formation temperature is not limited to a particular temperature unless it interferes with the present disclosure, and the film formation temperature is preferably 900° C. or lower, more preferably 700° C. or lower, and most preferably 400 to 700° C. Moreover, the film formation may be performed under any one of the following atmospheres: under vacuum, under non-vacuum, under a reducing gas atmosphere, under an inert gas atmosphere, and under an oxidation gas atmosphere and may be performed under any one of the following conditions: under ordinary pressure, under atmospheric pressure, under increased pressure, and under reduced pressure unless it interferes with the present disclosure; in the embodiment of the present disclosure, it is preferable that the film formation is performed under ordinary pressure or under atmospheric pressure. It is to be noted that a film thickness can be set by adjusting the film formation time.

The first lateral crystal growth layer generally contains a crystalline metal oxide as a major component. Examples of the crystalline metal oxide include a metal oxide containing one or two or more types of metal selected from aluminum, gallium, indium, iron, chromium, vanadium, titanium, rhodium, nickel, cobalt, iridium and so forth. In an embodiment of the present disclosure, the crystalline metal oxide preferably contains one or two or more types of elements selected from indium, aluminum, and gallium, more preferably contains at least indium or/and gallium, and is most preferably crystalline gallium oxide or a mixed crystal thereof. It is to be noted that, in an embodiment of the present disclosure, a “major component” means that the crystalline metal oxide constitutes preferably 50% or more, more preferably 70% or more, and further preferably 90% or more of all the components of the first lateral crystal growth layer in terms of atom ratio and means that the crystalline metal oxide may constitute 100% of all the components of the first lateral crystal growth layer in terms of atom ratio. The crystal structure of the crystalline metal oxide is not limited to a particular crystal structure; in an embodiment of the present disclosure, the crystal structure of the crystalline metal oxide is preferably a corundum structure or a β gallia structure and more preferably a corundum structure, and the first lateral crystal growth layer is most preferably a crystal growth film having a corundum structure. In an embodiment of the present disclosure, it is possible to obtain a crystal growth film having a corundum structure by performing the film formation using a substrate containing a corundum structure as the substrate. The crystalline metal oxide may be monocrystalline or polycrystalline; in an embodiment of the present disclosure, it is preferable that the crystalline metal oxide is monocrystalline. Moreover, the upper limit of the thickness of the first lateral crystal growth layer is not limited to a particular upper limit and is 100 μm, for example; the lower limit of the thickness of the first lateral crystal growth layer is also not limited to a particular lower limit and is preferably 3 μm, more preferably 10 μm, and most preferably 20 μm. In an embodiment of the present disclosure, the thickness of the first lateral crystal growth layer is preferably 3 to 100 μm, more preferably 10 to 100 μm, and most preferably 20 to 100 μm.

In an embodiment of the present disclosure, the projections are formed on the first lateral crystal growth layer as a mask. By forming the mask on the first lateral crystal growth layer as described above, it is possible to achieve not only a mere improvement in crystallinity, but also a large-area crystalline film. It is to be noted that the mask may be similar to the projections. In an embodiment of the present disclosure, it is preferable that the first lateral crystal growth layer includes two or more lateral crystal portions and the mask is placed on each of the two or more lateral crystal portions. It is to be noted that the two or more lateral crystal portions may be two or more lateral crystal portions obtained before the association of two or more first lateral crystal growth portions during the formation thereof in the first lateral crystal growth. By providing the mask on the lateral crystal portion as described above, it is possible to prevent warpage, cracks and so forth caused by thermal stress that is produced by the association in a first lateral crystal growth. It is preferable that the mask on the lateral crystal growth layer is patterned at regular intervals in a regular manner, and it is preferable that the spacing of the mask and/or openings on the lateral crystal growth layer is smaller than the spacing of the mask and/or openings on the substrate. By setting the spacing as described above, it is possible to achieve further relaxation of thermal stress or the like and more easily obtain a large-area crystalline film having high crystallinity. It is to be noted that the spacing of the mask and/or openings on the first lateral crystal growth layer is not limited to a particular spacing and is preferably 1 to 50 μm.

Moreover, in an embodiment of the present disclosure, a mask may be provided on the second lateral crystal growth layer and additional lateral crystal growth may be performed. Doing so makes it easier to obtain a large-area crystalline film that is 2 inches or larger and has a low dislocation density.

It is to be noted that, in an embodiment of the present disclosure, the first lateral crystal growth layer or the second lateral crystal growth layer may be formed as a separation sacrifice layer.

A crystalline film obtained by an embodiment of the production method in an embodiment of the present disclosure is suitably used in semiconductor devices in particular and is particularly useful for power devices. Examples of semiconductor devices that are formed using the crystalline film include transistors such as a MIS and a HEMT and TFTs, a Schottky barrier diode using the semiconductor-metal junction, a PN or PIN diode combined with another P layer, and a light-receiving or emitting element. In an embodiment of the present disclosure, the crystalline film may be used in a semiconductor device or the like as it is, or the crystalline film may be applied to a semiconductor device or the like after using a publicly known method such as separating the crystalline film from the substrate or the like.

### Embodiments

Hereinafter, embodiments of the present disclosure will be described; it is to be noted that the present disclosure is not limited to these embodiments.

### First Embodiment

### 1. Formation of Buffer Layer and Mask

### 1-1. Mist CVD Equipment

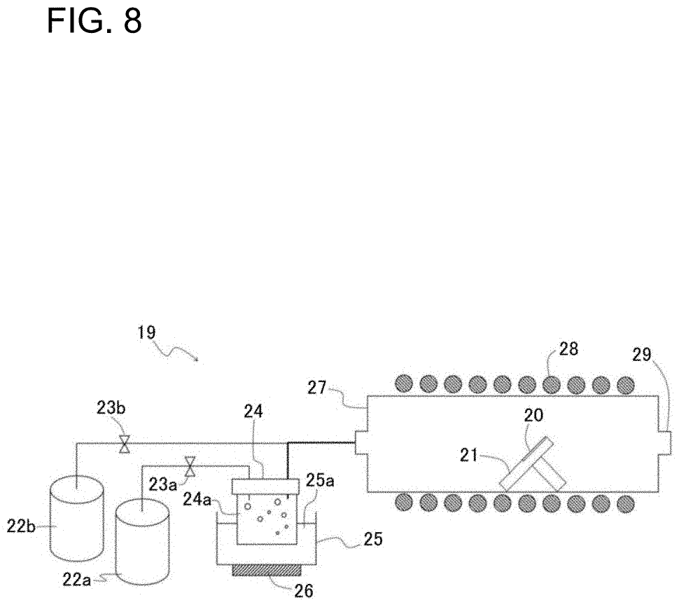

Mist CVD equipment 19 used in the present embodiment will be described using FIG. 8. The mist CVD equipment 19 includes a stage 21 on which a sample-to-be-subjected-to-film-formation 20 such as a substrate is placed, a carrier gas source 22a that supplies carrier gas, a flow control valve 23a for adjusting the flow rate of the carrier gas fed from the carrier gas source 22a, a carrier gas (dilute) supply source 22b that supplies carrier gas (dilute), a flow control valve 23b for adjusting the flow rate of the carrier gas (dilute) fed from the carrier gas source (dilute) 22b, a mist generation source 24 in which a raw material solution 24a is housed, a container 25 in which water 25a is put, an ultrasonic vibrator 26 attached to the bottom of the container 25, a film formation chamber 27 made up of a quartz tube having an inside diameter of 40 mm, and a heater 28 installed on the periphery of the film formation chamber 27. The stage is made of quartz, and a surface, on which the sample-to-be-subjected-to-film-formation 20 is placed, of the stage 21 is tilted with reference to a horizontal plane. Both the film formation chamber 27 and the stage 21 are made of quartz, which prevents contamination of a thin film to be formed on the sample-to-be-subjected-to-film-formation 20 by impurities derived from the equipment.

### 1-2. Preparation of Raw Material Solution

Gallium bromide and tin bromide were mixed into ultrapure water and the aqueous solution was adjusted in such a way that the atom ratio of tin to gallium was 1:0.08 and the aqueous solution contained 0.1 mol/L of gallium; in doing so, the aqueous solution was made to contain 20% hydrobromic acid in terms of volume ratio, and the obtained solution was used as a raw material solution.

### 1-3. Preparations for Film Formation

The raw material solution 24a obtained in 1-2. above was housed in the mist generation source 24. Then, a c-plane sapphire substrate was placed on the stage 21 as the sample-to-be-subjected-to-film-formation 20 and the temperature inside the film formation chamber 27 was raised to 460° C. by activating the heater 28. Next, the carrier gas was supplied to the inside of the film formation chamber 27 from the carrier gas source 22a and the carrier gas (dilute) source 22b by opening the flow control valves 23a and 23b and the atmosphere inside the film formation chamber 27 was sufficiently replaced with the carrier gas, and then the flow rate of the carrier gas was adjusted to 2.0 L/min and the flow rate of the carrier gas (dilute) was adjusted to 0.1 L/min. It is to be noted that nitrogen was used as the carrier gas.

### 1-4. Film Formation

Next, the ultrasonic vibrator 26 was vibrated at 2.4 MHz and the vibrations were transferred to the raw material solution 24a through the water 25a, whereby the raw material solution 24a was atomized and raw-material microparticles were generated. The raw-material microparticles were introduced into the film formation chamber 27 by the carrier gas, reacted with each other at 460° C. inside the film formation chamber 27, and formed a buffer layer on the sample-to-be-subjected-to-film-formation 20. It is to be noted that the film formation time was 5 minutes.

### 1-5. Mask Formation

A mask with openings having a dot pattern (a diameter: 5 μm) at a spacing of 50 μm was patterned on the buffer layer obtained in 1-4. above.

### 2. First Lateral Crystal Growth

### 2-1. HVPE System

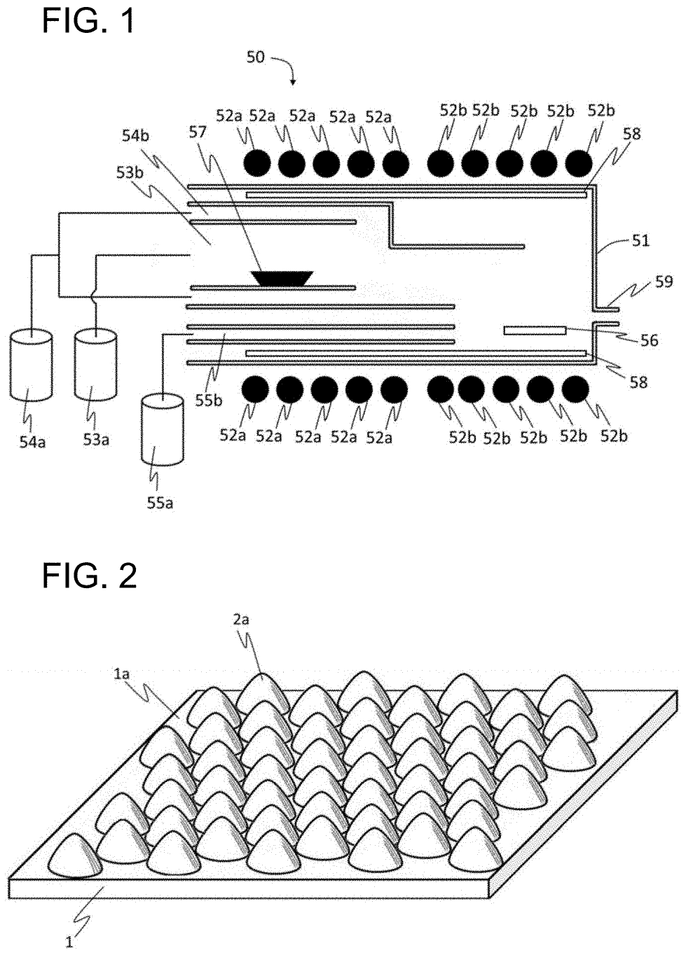

A halide vapor phase epitaxy (HVPE) system 50 used in the present embodiment will be described using FIG. 1. The HVPE system 50 includes a reaction chamber 51 and a heater 52a that heats a metal source 57 and a heater 52b that heats a substrate fixed to a substrate holder 56, and further includes, inside the reaction chamber 51, an oxygen-containing source gas supply pipe 55b, a reactive gas supply pipe 54b, and the substrate holder 56 on which the substrate is placed. The reactive gas supply pipe 54b has inside a metal-containing source gas supply pipe 53b, which forms a double-pipe structure. It is to be noted that the oxygen-containing source gas supply pipe 55b is connected to an oxygen-containing source gas supply source 55a and forms an oxygen-containing source gas channel such that oxygen-containing source gas can be supplied to the substrate fixed to the substrate holder 56 from the oxygen-containing source gas supply source 55a via the oxygen-containing source gas supply pipe 55b. Moreover, the reactive gas supply pipe 54b is connected to a reactive gas supply source 54a and forms a reactive gas channel such that reactive gas can be supplied to the substrate fixed to the substrate holder 56 from the reactive gas supply source 54a via the reactive gas supply pipe 54b. The metal-containing source gas supply pipe 53b is connected to a halogen-containing source gas supply source 53a, halogen-containing source gas is supplied to the metal source 57 and turns into metal-containing source gas, and the metal-containing source gas is supplied to the substrate fixed to the substrate holder 56. The reaction chamber 51 is provided with a gas exhaust portion 59 that discharges the used gas, and a protective sheet 58 that prevents the precipitation of a reactant is provided on the inner wall of the reaction chamber 51.

### 2-2. Preparations for Film Formation

A gallium (Ga) metal source 57 (purity 99.99999% or more) was placed inside the metal-containing source gas supply pipe 53b, and the sapphire substrate with the buffer layer and the dot-pattern mask obtained in 1 above was placed on the substrate holder 56 inside the reaction chamber 51 as the substrate. Then, the temperature inside the reaction chamber 51 was raised to 510° C. by activating the heaters 52a and 52b.

### 2-3. First Lateral Crystal Growth

Hydrogen chloride (HCl) gas (purity 99.999% or more) was supplied to the gallium (Ga) metal source 57 placed inside the metal-containing source gas supply pipe 53b from the halogen-containing source gas supply source 53a. Gallium chloride (GaCl/GaCl₃) was generated by a chemical reaction between the Ga metal of the metal source 57 and the hydrogen chloride (HCl) gas. The obtained gallium chloride (GaCl/GaCl₃) and O₂ gas (purity 99.99995% or more) supplied from the oxygen-containing source gas supply source 55a were supplied to the space above the substrate through the metal-containing raw material supply pipe 53b and the oxygen-containing source gas supply pipe 55b, respectively. In doing so, hydrogen chloride (HCl) gas (purity 99.999% or more) was supplied to the space above the substrate from the reactive gas supply source 54a through the reactive gas supply pipe 54b. Then, a film was formed on the substrate by making the gallium chloride (GaCl/GaCl₃) and the O₂ gas react with each other on the substrate under atmospheric pressure at 510° C. with the HCl gas being circulated. It is to be noted that the film formation time was 25 minutes. The flow rate of the HCl gas supplied from the halogen-containing source gas supply source 53a was maintained at 10 sccm, the flow rate of the HCl gas supplied from the reactive gas supply source 54a was maintained at 5.0 sccm, and the flow rate of the O₂ gas supplied from the oxygen-containing source gas supply source 55a was maintained at 20 sccm. A large number of columnar crystals due to crystalline association were observed in the obtained film.

### 3. Mask Formation

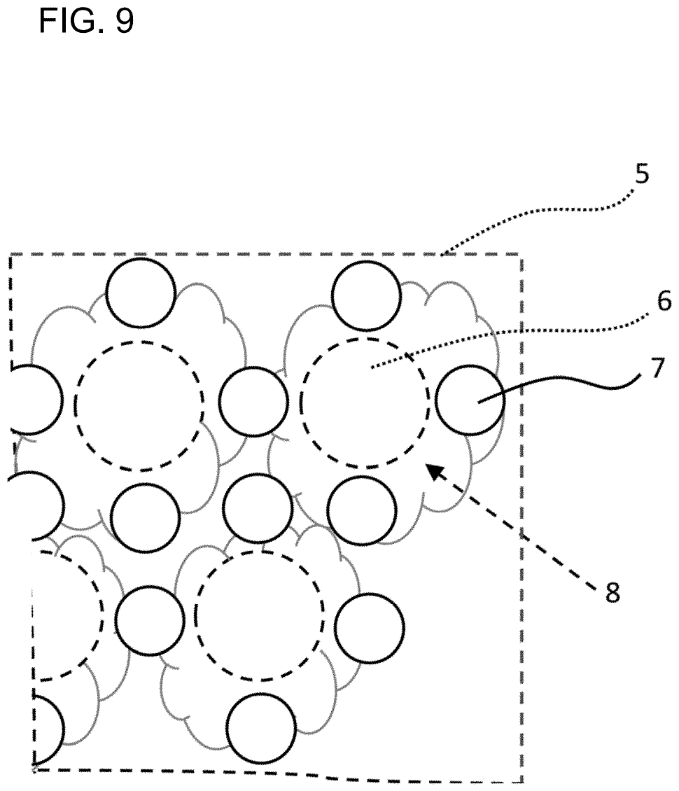

A mask with openings having a dot pattern (a diameter: 5 μm) with 5 μm spacing was patterned in a position corresponding to an area on a lateral growth portion in a columnar crystal of the crystalline film obtained in 2. above. FIG. 9 shows the relationship between a mask and a first lateral crystal growth layer. A mask 5 is formed on the c-plane sapphire substrate. Crystal growth progressed from an opening 6 and a columnar crystal 8 was formed, and first lateral crystal growth was stopped before association. A mask 7 is formed on a first lateral crystal growth layer, which is not located immediately above the opening 6, in the columnar crystal 8.

### 4. Second Lateral Crystal Growth

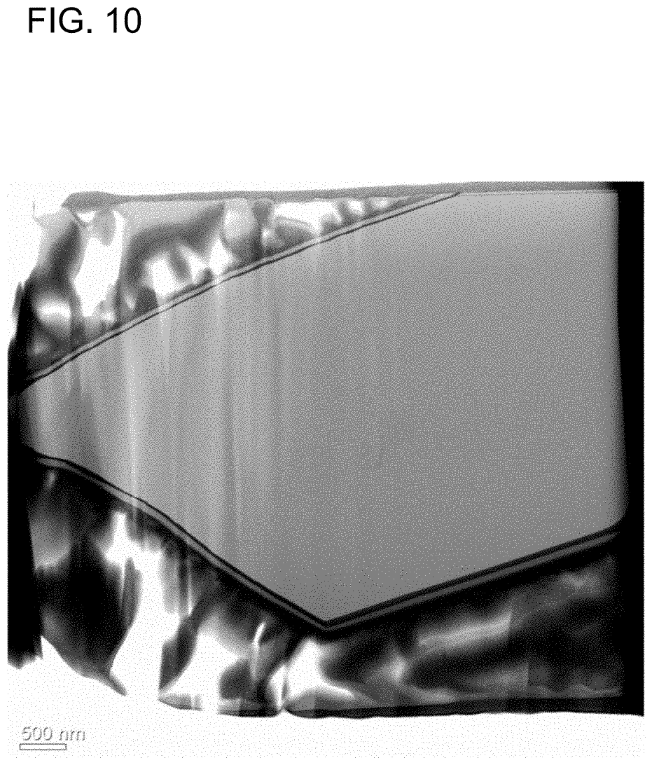

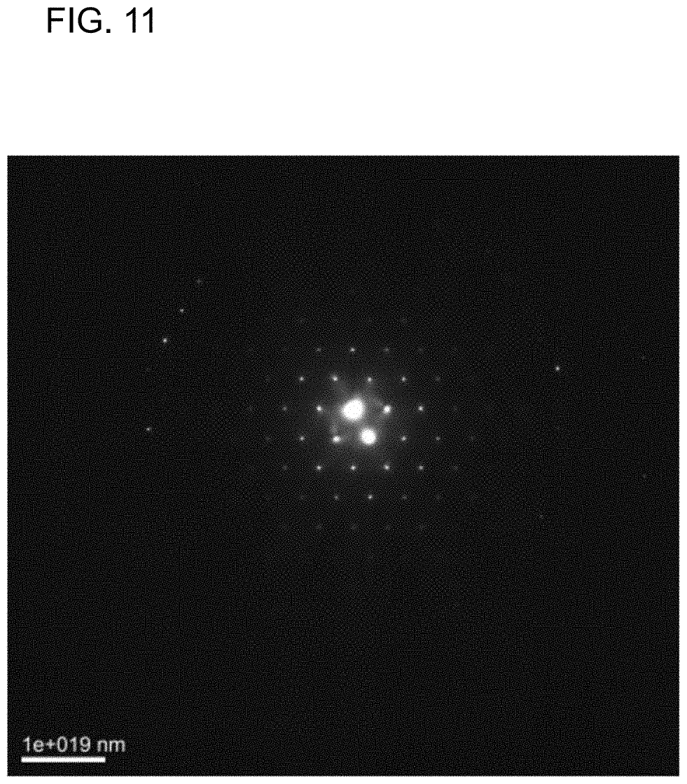

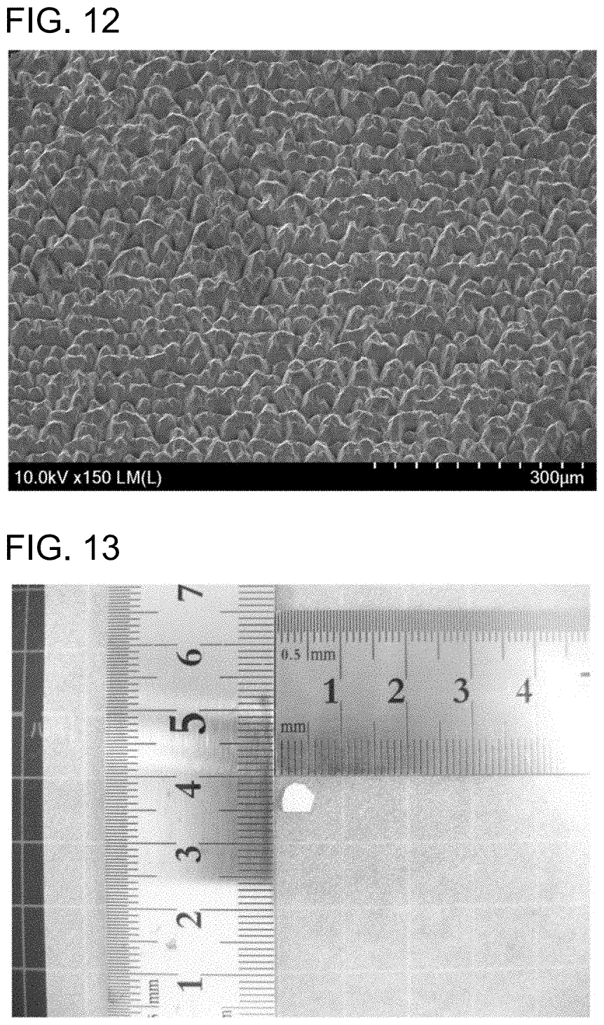

A crystalline film was obtained by performing crystal growth in a manner similar to the manner of 2. above using the film obtained in 3. above. The obtained crystalline film was a clean film free of cracks and abnormal growth. An identification of the obtained film was made by performing 2θ/ω scanning at an angle of 15 to 95 degrees using an XRD diffraction instrument for a thin film. The measurements were performed using CuKα rays. The results indicated that the obtained film was α-Ga₂O₃. It is to be noted that the film thickness of the obtained crystalline film was 100 μm. As shown in FIG. 10, TEM observations of the obtained film revealed that a very clean film was obtained. It is to be noted that curtain-like white portions in FIG. 10 were caused by polishing irregularities at the time of fabrication of a sample for TEM observations and are not threading dislocations or the like (the curtain effect). Moreover, the obtained crystalline film has a dislocation density of 5.23×10⁶ cm⁻² which is less than 1×10⁷ cm⁻². Furthermore, as shown in FIG. 11, it was verified that the obtained film was an α-Ga₂O₃ film in a SAED pattern too. Moreover, as shown in FIG. 12, observations of the state of the association of a crystal by a SEM revealed that it was the state of the association of islands of α-Ga₂O₃, and it was verified that a large-area α-Ga₂O₃ film was achieved by crystalline association. It is to be noted that, as shown in FIG. 13, the surface area of the obtained crystalline film was 15 mm².

### Second Embodiment

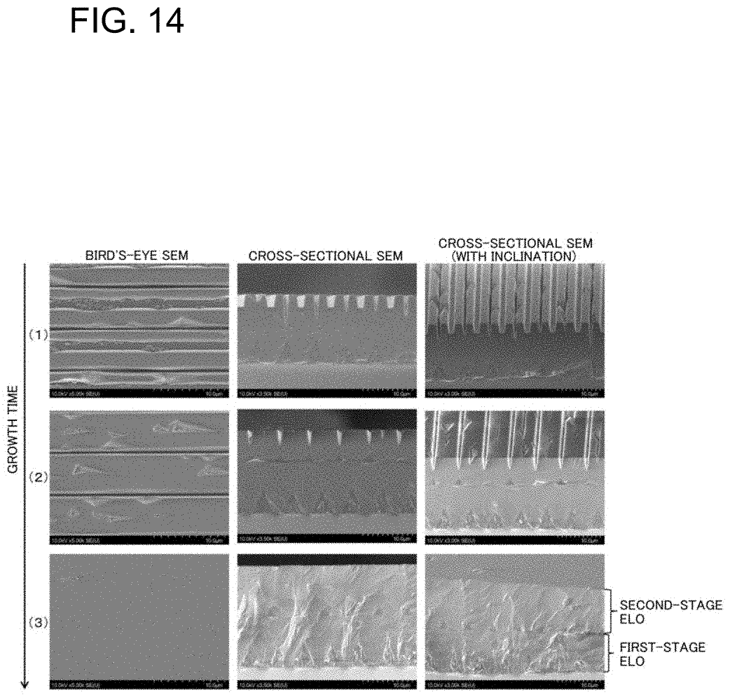

A crystalline film was obtained by a manner similar to the manner from 2. to 4. above except that a mask having a 4 μm wide line pattern parallel to an m-axis was patterned at a spacing of 2 μm (a spacing is also refereed to as an opening of the mask) in a striped pattern at 6-μm intervals on the buffer layer obtained in 1-4. above and a mask having a line pattern and patterned in the striped pattern was used as a mask in 3. above. FIG. 14 shows a bird's-eye SEM image, a cross-sectional SEM image, and a cross-sectional SEM image (with inclination) obtained when a crystalline film was grown for varying lengths of growth time using the mask pattern of a second embodiment. The growth time was made longer in the order of crystalline films (1), (2), and (3). In the crystalline film (3), first lateral growth is shown as first-stage ELO and second lateral growth is shown as second-stage ELO. It was verified that the obtained crystalline film was an α-Ga₂O₃ film in a SAED pattern too. As is clear from the SEM images of FIG. 14, by making the growth time longer, the crystalline association of α-Ga₂O₃ in a line pattern progressed, which made it possible to obtain a planarized film.

The crystalline film in an embodiment of the present disclosure can be used in all the fields such as semiconductors (for example, a compound semiconductor electronic device), electronic parts, electrical apparatus parts, optical and electronic photograph-related equipment, and industrial components, and is particularly useful for, for example, production of a semiconductor device.

### REFERENCE SIGNS LIST

a interval

1 substrate main body

1a front surface of a substrate

2a projections

2b depressions

5 mask (on a substrate)

6 opening of a mask

7 mask (on a first lateral crystal growth layer)

8 first lateral crystal growth layer

19 mist CVD equipment

20 sample-to-be-subjected-to-film-formation

21 stage

22a carrier gas source

22b carrier gas (dilute) source

23a flow control valve

23b flow control valve

24 mist generation source

24a raw material solution

25 container

25a water

26 ultrasonic vibrator

27 film formation chamber

28 heater

50 halide vapor phase epitaxy (HVPE) system

51 reaction chamber

52a heater

52b heater

53a halogen-containing source gas supply source

53b metal-containing source gas supply pipe

54a reactive gas supply source

54b reactive gas supply pipe

55a oxygen-containing source gas supply source

55b oxygen-containing source gas supply pipe

56 substrate holder

57 metal source

58 protective sheet

59 gas exhaust portion

What is claimed is:

1. A crystalline film comprising:
a crystalline metal oxide as a major component;
a corundum structure;
a dislocation density of 1×10⁷ cm⁻² or less; and
a surface area of 10 mm² or more.

2. The crystalline film according to claim 1,
wherein the crystalline metal oxide contains at least gallium.

3. The crystalline film according to claim 1, further comprising:
two or more lateral crystal growth layers.

4. A crystalline film comprising:
a crystalline metal oxide as a major component;
a corundum structure;
at least one or more lateral crystal growth layers; and
a surface area of 10 mm² or more.

5. The crystalline film according to claim 1, further comprising:
a dopant.

6. A semiconductor device comprising:
a crystalline film,
wherein the crystalline film is the crystalline film according to claim 1.

7. The semiconductor device according to claim 6,
wherein the semiconductor device is a power device.

8. A method of producing a crystalline film comprising:
forming a first lateral crystal growth layer on a substrate by a first lateral crystal growth;
placing a mask on the first lateral crystal growth layer; and
forming a second lateral crystal growth layer by a second lateral crystal growth.

9. The production method according to claim 8,
wherein the first lateral crystal growth is performed by HVPE or mist CVD.

10. The production method according to claim 8,
wherein the second lateral crystal growth is performed by HVPE or mist CVD.

11. The production method according to claim 8,
wherein the mask is placed in a dot pattern on the first lateral crystal growth layer.

12. The production method according to claim 8,
wherein the mask has openings having a dot pattern and is placed on the first lateral crystal growth layer.

13. The production method according to claim 8,
wherein the mask has a line shape.

14. The production method according to claim 8,
wherein the first lateral crystal growth layer has a corundum structure.

15. The production method according to claim 8,
wherein the first lateral crystal growth layer contains gallium.

16. The production method according to claim 8,
wherein the second lateral crystal growth layer has a corundum structure.

17. The production method according to claim 8,
wherein the second lateral crystal growth layer contains gallium.

18. The production method according to claim 8,
wherein the first lateral crystal growth layer includes two or more lateral crystal portions, and
wherein the mask is placed on each of the two or more lateral crystal portions.

19. The production method according to claim 8,
wherein the mask and/or openings are patterned at regular intervals in a regular manner.

20. The production method according to claim 8,
wherein a mask is placed on a substrate and the first lateral crystal growth layer is formed by first lateral crystal growth.

21. The production method according to claim 20,
wherein the mask and/or openings on the substrate are patterned at regular intervals in a regular manner, and
wherein a spacing of the mask and/or openings on the substrate is larger than a spacing of the mask on the first lateral crystal growth layer.

22. The production method according to claim 21,
wherein the spacing of the mask and/or openings on the substrate is 10 to 100 μm, and
wherein the spacing of the mask and/or openings on the first lateral crystal growth layer is 1 to 50 μm.
